(19) United States
(12) Patent Application Publication
(10) Pub. No.: US 2007/0295482 A1
(43) Pub. Date: Dec. 27, 2007

(54) Heat spreader for use in conjunction with a semiconducting device and method of manufacturing same

(76) Inventors: Thomas J. Fitzgerald, Phoenix, AZ (US); Mario Montano, Scottsdale, AZ (US); Chuan Hu, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/473,945

(22) Filed: Jun. 23, 2006

(51) Int. Cl. H05K 7/20

(52) U.S. Cl. 165/80.4; 361/699; 257/714; 29/890.03

(57) ABSTRACT

A heat spreader includes a body (110) having a first surface (111) and a second surface (112), a first metal layer (120) coating substantially all of the body, a second metal layer (130) over a portion of the first metal layer, and a lip (140) protruding from the second surface. In a particular manifestation, the heat spreader is a microchannel (200, 400, 500) including a base plate (210) and a cover (220, 410, 510), where the base plate includes spaced-apart first and second surfaces (211), (212) and a plurality of fins (213) at the second surface, and the cover includes a third surface (221) having a cavity (222) therein capable of receiving the plurality of fins, a fourth surface (223, 411, 511) spaced apart from the third surface, and a lip or other grip (224, 412, 512) adjacent to the fourth surface.

### FIELD OF THE INVENTION

This invention relates generally to thermal management in microelectronic systems, and relates more particularly to heat spreaders for use with semiconducting devices.

### BACKGROUND OF THE INVENTION

The microelectronics industry continues to place an increasing number of electronic devices in an increasingly smaller area. Thus, for example, there currently exist computer chips having dimensions of just a few square millimeters that contain tens of millions of transistors. The electrical activity that takes place within such electronic devices generates a considerable amount of heat which, if not properly managed, can cause significant damage to the electronic devices and other components of a microelectronics system.

Various cooling systems and cooling technologies have been developed in order to manage heat in microelectronics systems. Many such cooling systems include a component such as a heat spreader for the purpose of judiciously distributing heat throughout the microelectronics system. Heat spreaders come in various forms and include microchannels, vapor chambers, cold plates, heat exchangers, heat pipes, and others. Some types of heat spreaders, including microchannels, are subjected to high temperature processing steps during their manufacture that can cause portions of these heat spreaders to become warped and deformed, thus taking such heat spreaders outside of their flatness specifications. For such heat spreaders the referred-to warping and deformation appears to be an unavoidable by-product of their manufacture.

Flatness of the heat spreader bonding surface is of great importance when bonding heat spreaders to silicon dies with solder thermal interface material (TIM). A bonding surface that is even slightly warped can lead to increased solder voiding and can decrease thermal performance. A light grinding or polishing operation would be desirable to flatten out the bonding surface of the heat spreader, but current heat spreader designs and configurations do not allow it, for physical and other reasons. Accordingly, there exists a need for a heat spreader capable of being brought to within acceptable flatness specifications while maintaining its structural integrity and thermal performance.

### BRIEF DESCRIPTION OF THE DRAWINGS

The invention will be better understood from a reading of the following detailed description, taken in conjunction with the accompanying figures in the drawings in which:

FIG. 1 is a cross sectional view of a heat spreader for use in conjunction with a semiconducting device according to an embodiment of the invention;

FIG. 2 is a cross sectional view of a microchannel according to an embodiment of the invention;

FIG. 3 is a top view of the microchannel of FIG. 2 according to an embodiment of the invention;

FIGS. 4 and 5 are top views of microchannels according to different embodiments of the invention;

FIG. 6 is a flowchart illustrating a method of manufacturing a heat spreader for use in conjunction with a semiconducting device according to an embodiment of the invention;

FIG. 7 is a flowchart illustrating a method of manufacturing a microchannel for use in conjunction with a semiconducting device according to an embodiment of the invention;

FIG. 8 is a side view of a cointube in which a first and a second microchannel are located according to an embodiment of the invention;

FIG. 9 is a flowchart illustrating a method of preparing a microchannel for transport according to an embodiment of the invention; and

FIG. 10 is a schematic view of a system in which a heat spreader according to an embodiment of the invention may be utilized.

For simplicity and clarity of illustration, the drawing figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner.

### DETAILED DESCRIPTION OF THE DRAWINGS

In one embodiment of the invention, a heat spreader for use in conjunction with a semiconducting device comprises a body having a first surface and a second surface that are spaced apart from each other, a first metal layer coating substantially all of the body, a second metal layer over a portion of the first metal layer at the first surface, and a lip protruding from the second surface. In a particular manifestation, the heat spreader comprises a microchannel comprising a base plate and a cover disposed over the base plate, where the base plate comprises spaced-apart first and second surfaces and a plurality of fins at the second surface, and the cover comprises a third surface having a cavity therein capable of receiving the plurality of fins, a fourth surface spaced apart from the third surface, and a lip or other grip adjacent to the fourth surface.

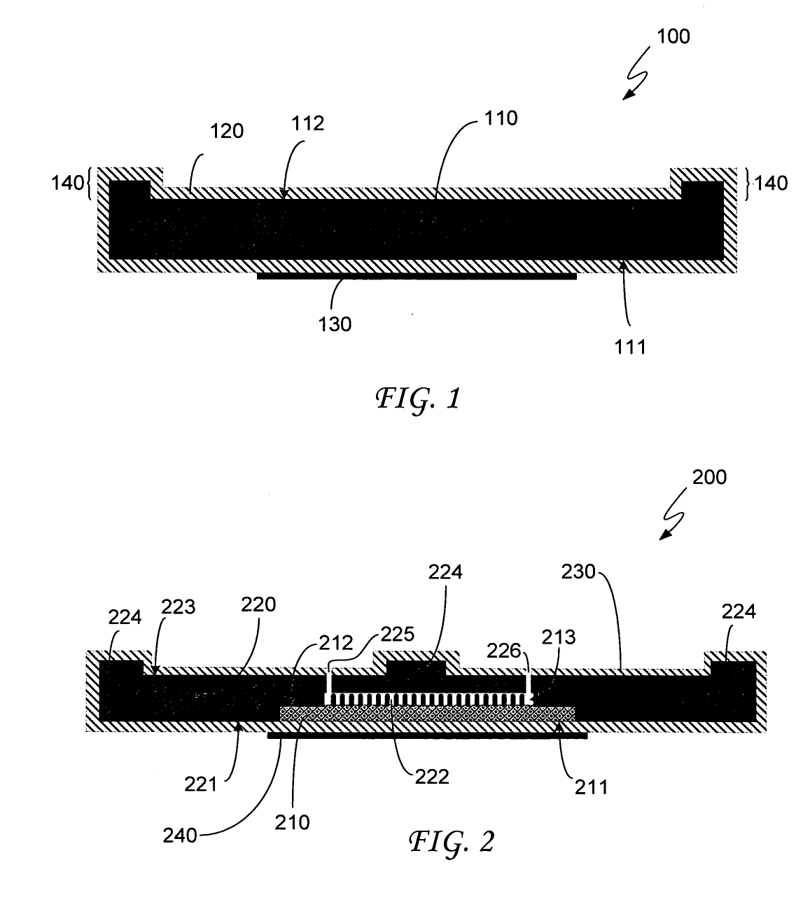

Referring now to the drawings, FIG. 1 is a cross sectional view of a heat spreader 100 for use in conjunction with a semiconducting device according to an embodiment of the invention. As an example, heat spreader 100 can be an integral heat spreader, a vapor chamber, a cold plate, a heat exchanger, a heat pipe, or some other thermal solution. In a particular embodiment, to be discussed in greater detail below, heat spreader 100 is a microchannel.

As illustrated in FIG. 1, heat spreader 100 comprises a body 110 having a surface 111 and a surface 112 spaced apart from surface 111. A metal layer 120 coats substantially all of body 110 and a metal layer 130 is disposed over a portion of metal layer 120 at surface 111. Heat spreader 100 further comprises a lip 140 protruding from surface 112.

In one embodiment, body 110 comprises copper. In the same or another embodiment, metal layer 120 comprises nickel and metal layer 130 comprises gold. As an example, metal layer 120 can have a thickness of approximately 3 micrometers and metal layer 130 can have a thickness of approximately 0.2 micrometers. A reason for including metal layer 120 of nickel, as known in the art, is that a nickel layer can act as a diffusion barrier to prevent the gold from diffusing into the copper. As is also known in the art, a gold layer, because gold does not oxidize, provides a good wetting surface for solder that may be applied during the assembly of a package containing heat spreader 100.

The presence of lip 140 provides several advantages. Among them are that lip 140 serves as a handle that may be gripped while heat spreader 100 is being worked with, that lip 140 acts as a stiffener that prevents heat spreader 100 from flexing or bending, and that lip 140 acts as a bonding surface, a stand-off, or a fiducial for a manifold or the like. Additional advantages provided by lip 140 will be discussed in detail below.

It was mentioned above that in one embodiment of the invention heat spreader 100 is a microchannel. Accordingly, FIG. 2 is a cross sectional view of a microchannel 200 according to an embodiment of the invention. As illustrated in FIG. 2, microchannel 200 comprises a base plate 210 and a cover 220 disposed over base plate 210. Base plate 210 comprises a surface 211, a surface 212 spaced apart from surface 211, and a plurality of fins 213 at surface 212. Cover 220 comprises a surface 221 containing a cavity 222 capable of receiving plurality of fins 213. Cover 220 further comprises a surface 223 spaced apart from surface 221 and a grip 224 adjacent to surface 223. As an example, grip 224 could be a lip similar to lip 140 (see FIG. 1) rising above or protruding from surface 223. As another example, grip 224 could be a depression or similar feature extending into surface 223.

In the embodiment illustrated in FIG. 2, microchannel 200 further comprises a fluid aperture 225 and a fluid aperture 226, one of which may be a fluid inlet hole and the other of which may be a fluid outlet hole. As known in the art, fluid apertures 225 and 226 may be used as a mechanism to introduce a cooling fluid to cavity 222 and to plurality of fins 213 and to remove cooling fluid from cavity 222 after it has passed across plurality of fins 213. The cooling fluid picks up heat that has been generated by a microelectronic device to which microchannel 200 is attached and transfers such heat away from the microelectronic device when it exits cavity 222. In a particular embodiment, fluid apertures 225 and 226 may be circular, with a diameter of approximately three millimeters.

Microchannel 200 may still further comprise a metal layer 230 that coats substantially all of surfaces 211, 221, and 223 and a metal layer 240 over a portion of metal layer 230 at or near surface 211, as illustrated. As an example, metal layers 230 and 240 can be similar to, respectively, metal layers 120 and 130 that were shown in FIG. 1. Note that although metal layer 230 is described as coating substantially all of surface 221 it should not be inferred, at least with respect to the illustrated embodiment, that metal layer 230 coats cavity 222, even though cavity 222 may possibly be thought of as an extension of or a portion of surface 221. Rather, as shown, metal layer 230 continues in a substantially straight line across the boundaries where surfaces 211 and 221 meet.

Cover 220, plurality of fins 213, and base plate 210 may be made of copper, silicon, aluminum, diamond, tungsten, silver, or the like, or of composites or alloys of the foregoing materials. As known in the art, copper is less brittle, and therefore easier to work with, than silicon so that a microchannel having the foregoing or other components made of copper instead of silicon may possibly lead to better thermal and other performance of the microchannel. As an example, the greater ease of workability of copper means that adjacent ones of plurality of fins 213 may be spaced apart from each other by a distance of between approximately 50 and 100 micrometers. Such close spacing of adjacent fins enables an increased number of fins in a given volume, leading to an increased surface area and a corresponding increase in heat transfer efficiency when compared to a silicon microchannel.

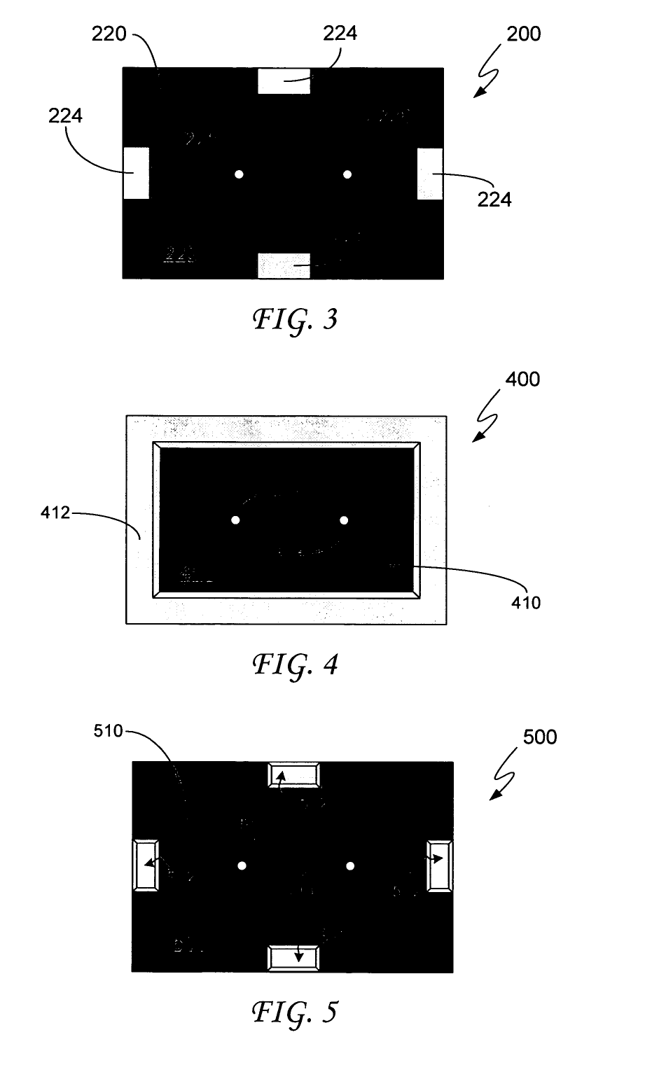

In the embodiment illustrated in FIG. 2, grip 224 is a lip protruding from surface 223. Also in that embodiment, microchannel 200 comprises a plurality of such grips, all of which are labeled using reference numeral 224. Three grips 224 are visible in FIG. 2. A fourth grip 224 is not visible in FIG. 2 but may be seen in FIG. 3, which is a top view of microchannel 200 according to an embodiment of the invention. (For purposes of clarity and simplicity, metal layer 230 is not shown in FIG. 3, leaving surface 223 as the top visible layer.) As illustrated in FIG. 3, microchannel 200 includes four grips 224 in the form of lips protruding from surface 223 and distributed roughly evenly along a perimeter of surface 223. With grips 224 in the illustrated arrangement and quantity they are well-suited to provide the potential advantages listed above as well as those to be discussed below. It should be understood, however, that other types, arrangements, and quantities of grip 224 may also be desirable. Some of these other embodiments are depicted in subsequent figures and discussed in connection therewith.

One such other embodiment is illustrated in FIG. 4, which is a top view of a microchannel 400 according to an embodiment of the invention. (As was the case in FIG. 3, any metal layer that may coat the upper surface of microchannel 400 is omitted for purposes of clarity and simplicity.) With certain exceptions, including details to be described immediately below regarding the configuration of the grips, microchannel 400 can be similar to microchannel 200, first shown in FIG. 2. As illustrated in FIG. 4, microchannel 400 comprises a cover 410, of which a surface 411 is visible. A fluid aperture 413 and a fluid aperture 414, which may be similar to fluid apertures 225 and 226 first shown in FIG. 2, extend into surface 411. Protruding from surface 411 is a grip 412 in the form of a ring running around a perimeter of surface 411, which ring may serve the same or similar functions and provide the same or similar advantages as the functions and advantages served and provided by grips 224 that were first shown in FIG. 2. In one embodiment, grip 412 is a substantially continuous ring running around the entire perimeter of surface 411. In other embodiments grip 412 may be broken in places so that it has the general form of a ring but is not completely continuous. Furthermore, in one or more of those other embodiments grip 412 need not be located at the perimeter of surface 411 but can instead be located at some other point on surface 411.

FIG. 5 is a top view of a microchannel 500 according to an embodiment of the invention. (As was the case in FIG. 3, any metal layer that may coat the upper surface of microchannel 500 is omitted for purposes of clarity and simplicity.) FIG. 5 illustrates another one of the alternatives regarding the grip that is part of a microchannel. With certain exceptions, including details to be described immediately below regarding the configuration of the grips, microchannel 500 can be similar to microchannel 200, first shown in FIG. 2.

As illustrated in FIG. 5, microchannel 500 comprises a cover 510, of which a surface 511 is visible. Located on surface 511 are fluid apertures 513 and 514, which may be similar to fluid apertures 225 and 226 that were first shown in FIG. 2, and a plurality of grips 512 in the form of depressions extending into surface 511. Grips 512 may serve the same or similar functions and provide the same or similar advantages as the functions and advantages served and provided by grips 224, first shown in FIG. 2. Four depressions are shown in FIG. 5, and a microchannel with four depressions may be especially well-suited to provide the advantages offered by the presence of a grip. Even so, the presence of four depressions is not a requirement. Two depressions may be a practical minimum, but the number of depressions is not limited to two or to four. Rather, microchannel 500, as well as the other microchannels and heat spreaders described herein, can have any number, whether smaller or greater than two or four, of lips, depressions, or other grips. Furthermore, it should be understood that the illustrated quantities, arrangements, and types of grips do not represent all possible embodiments, but rather are merely illustrative of a greater number of possible embodiments.

The foregoing discussion has alluded to several potential advantages made possible by the presence of grips or similar features on an upper surface of a microchannel cover or the like. Some of the potential advantages represent solutions to problems that may arise in the manufacture of microchannels or other heat spreaders. These potential advantages, together with a description of some of the problems they may solve, will now be discussed in greater detail.

In a typical arrangement, a heat spreader is bonded to a die or another package component using a solder thermal interface material (TIM) process or the like. The bonding surface of the heat spreader, corresponding for example to surface 111 of heat spreader 100 and to surface 221 of microchannel 200, must be substantially flat in order to prevent the creation of voids in the solder TIM bondline after package assembly. In this context, “substantially flat” can mean that no height variation greater than approximately 35 micrometers is allowed. Any warping that takes the flatness of the bonding surface beyond that upper spec limit of approximately 35 micrometers can lead to increased and unacceptable solder voiding and can significantly decrease thermal performance.

In applications or embodiments where the heat spreader is a microchannel certain additional complications can arise, especially where the microchannel is made of copper. For example, cutting the grooves in the base of a copper microchannel (in a process that creates the fins) causes the underlying copper plate to warp during manufacturing. In addition, the cutting process imparts a large amount of plastic deformation, or cold work, into the copper. The other components of the copper microchannel, including the cover, are typically copper stampings that have also experienced a large amount of plastic deformation. Unfortunately, especially for large parts such as premium server products for which copper microchannels as large as approximately 50 by 50 millimeters or even 100 by 100 millimeters may be used, very little plastic deformation is required in order to cause warpage beyond the upper spec limit for flatness.

Copper has a re-crystallization temperature that depends on the amount of plastic deformation to which the copper has been exposed. Copper that has undergone a significant degree of plastic deformation, which for the reasons set forth above includes copper in a typical copper microchannel, can easily have a re-crystallization temperature in the range of approximately 250 to 300 degrees Celsius. A re-crystallization temperature in this range is problematic for copper microchannels because: (1) warpage and deformation of copper components are known to occur when copper re-crystallizes; and (2) copper microchannels typically undergo a brazing process during their manufacture at temperatures that, if not yet precisely defined, almost certainly exceed 250 degrees Celsius. Differences in the coefficients of thermal expansion (CTE) between the copper and the braze material, which may be silver paste or the like, may cause further dimensional changes as the microchannel cools from the brazing temperature to room temperature. The result is that the sub-components of a copper microchannel, including the base plate and the cover, will very likely fall outside of the upper spec limit for flatness after manufacturing, meaning that, after normal manufacturing, the microchannel will very likely not be sufficiently flat for solder TIM voiding to be avoided.

When the base plate and the cover of the microchannel are brazed together, drips of braze may occasionally end up on the bonding surface of the microchannel, which can interfere with the bondline on the assembled package. In addition, the exposed copper will likely be oxidized during brazing, making subsequent plating operations, as with nickel and gold, more difficult.

The foregoing and other problems may be overcome, and the bonding surface of the microchannel may be brought within the upper spec limit for flatness, through the performance of a grinding or polishing operation that follows the manufacture of the microchannel. It is the presence of grips such as those described above that makes such grinding or polishing possible. As mentioned earlier, the grips act as a handle such that the microchannel may be securely grasped during grinding or polishing and also act as a stiffener that prevents the microchannel from flexing. Note that if the grips were placed on the bonding surface they would interfere with the grinding or polishing operations; hence the placement of the grips on the surface opposite the bonding surface. Also note that either or both of the grinding and polishing operations may be used.

Another advantage attributable to the grips is that grinding or polishing the bonding surface will remove any drips of braze and any oxidized copper from that surface that resulted from the brazing operation. Furthermore, grinding or polishing the bonding surface of the microchannel or other heat spreader removes some of the bonding surface, resulting in a thinned bonding surface which will improve thermal performance. As an example, with reference to FIG. 2, base plate 210 may have a thickness, i.e., a shortest distance between surfaces 211 and 212, no greater than approximately 500 micrometers following the grinding or polishing operation. In a particular embodiment the grinding or polishing operation may result in base plate 210 having a thickness as small as approximately 100 micrometers or less.

Yet another advantage of the grips is possible in an embodiment like those shown in FIGS. 1-4 where the grips take the form of lips or rings protruding from the surface of the cover of the microchannel. The additional advantage is that it becomes possible to stack multiple microchannels vertically without scratching or otherwise marring a surface of the microchannel. As an example, multiple microchannels or other heat spreaders can be stacked vertically in a cointube, as will be further discussed below.

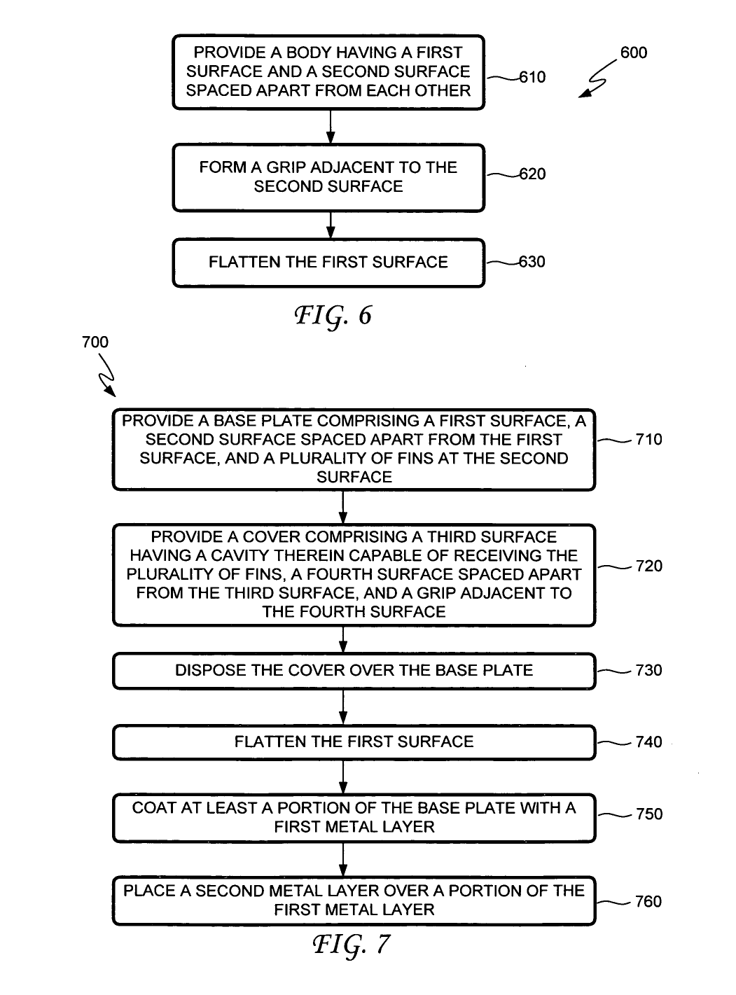

FIG. 6 is a flowchart illustrating a method 600 of manufacturing a heat spreader for use in conjunction with a semiconducting device according to an embodiment of the invention. A step 610 of method 600 is to provide a body having a first surface and a second surface spaced apart from each other. As an example, the body can be similar to body 110 shown in FIG. 1. As another example, the first surface and the second surface can be similar to, respectively, surface 111 and surface 112, both of which were also shown in FIG. 1.

A step 620 of method 600 is to form a grip adjacent to the second surface, which surface, at least in one embodiment, is opposite the bonding surface of the heat spreader. As an example, the grip can be similar to one or more of lip 140, grip 224, grip 412, and grip 512. As another example, the grip can be created using techniques of stamping, casting, grinding, machining, or the like.

A step 630 of method 600 is to flatten the first surface. As an example, step 630 can comprise at least one of polishing the first surface and grinding the first surface. As another example, step 630 is performed while the heat spreader is being held onto by the grip formed in step 620. In one embodiment, step 630 also removes braze material and/or oxide from the first surface.

FIG. 7 is a flowchart illustrating a method 700 of manufacturing a microchannel for use in conjunction with a semiconducting device according to an embodiment of the invention. A step 710 of method 700 is to provide a base plate comprising a first surface, a second surface spaced apart from the first surface, and a plurality of fins at the second surface. As an example, the base plate, the first surface, the second surface, and the plurality of fins can be similar to, respectively, base plate 210, surface 211, surface 212, and plurality of fins 213, all of which were first shown in FIG. 2.

A step 720 of method 700 is to provide a cover comprising a third surface having a cavity therein capable of receiving the plurality of fins, a fourth surface spaced apart from the third surface, and a grip adjacent to the fourth surface. As an example, the cover, the third surface, the cavity, the fourth surface, and the grip can be similar to, respectively, cover 220, surface 221, cavity 222, surface 223, and grip 224, all of which were first shown in FIG. 2. Alternatively, the grip can be similar to grip 412, shown in FIG. 4, or grip 512, shown in FIG. 5.

A step 730 of method 700 is to dispose the cover over the base plate. As an example, step 730 can comprise positioning the cover over the base plate such that the plurality of fins are in the cavity, placing a brazing material on at least a portion of at least one of the base plate and the cover, and brazing the base plate and the cover to each other.

A step 740 of method 700 is to flatten the first surface. As an example, step 740 can comprise at least one of polishing the first surface and grinding the first surface. As another example, step 740 is performed while the heat spreader is being held onto by the grip provided in step 720. In one embodiment, step 740 also removes from the first surface braze material and/or oxide that may be there as a result of the performance of step 730 or another step. In the same or another embodiment step 740 comprises flattening the first surface to a flatness of at least approximately 35 micrometers.

A step 750 of method 700 is to coat at least a portion of the base plate with a first metal layer. As an example, the first metal layer can be similar to metal layer 120 in FIG. 1.

A step 760 of method 700 is to place a second metal layer over a portion of the first metal layer. As an example, the second metal layer can be similar to metal layer 130 in FIG. 1.

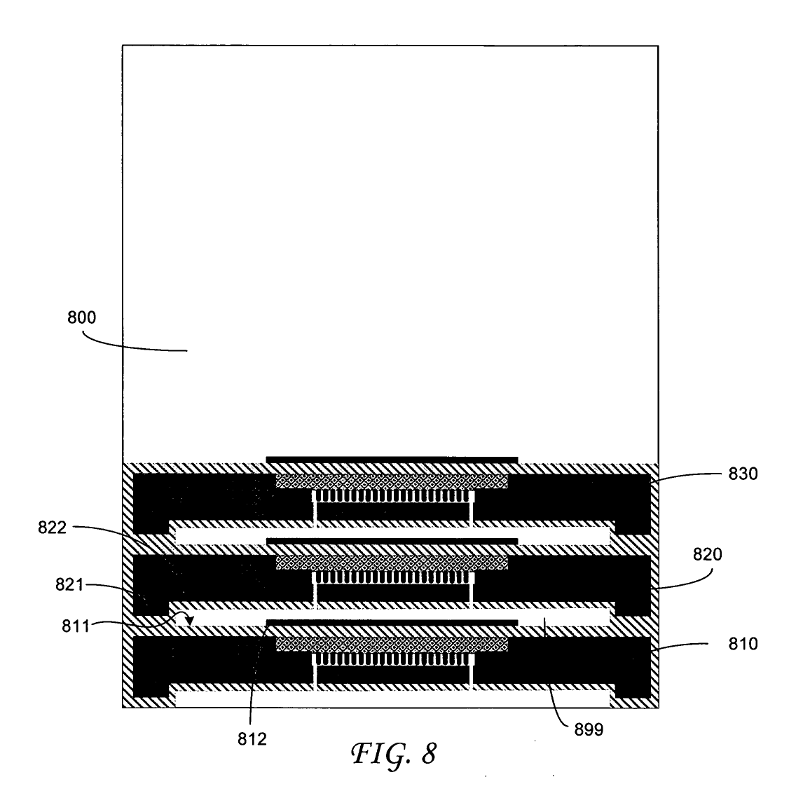

FIG. 8 is a side view of a cointube 800 in which microchannels 810, 820, and 830 are located according to an embodiment of the invention. Cointube 800 is shown with a transparent front wall so that the contents of the cointube may be seen. (Although only three microchannels are shown in FIG. 8, a typical cointube will likely contain as many as 100 microchannels or more, and cointube 800 is thus shown with empty space for such additional microchannels above microchannel 830.) As illustrated in FIG. 8, a grip 821 adjacent to a surface 822 of microchannel 820 contacts a surface 811 of microchannel 810. A metal layer 812 is located adjacent to a portion of surface 811. As illustrated, the presence of grip 821 creates a space 899 in which metal layer 812 can rest without being contacted by any portion of microchannel 820 or of any other microchannel in cointube 800. In this way metal layer 812 is protected so that it is not scratched or damaged during transport. Corresponding metal layers of other microchannels in cointube 800 are protected in a similar manner.

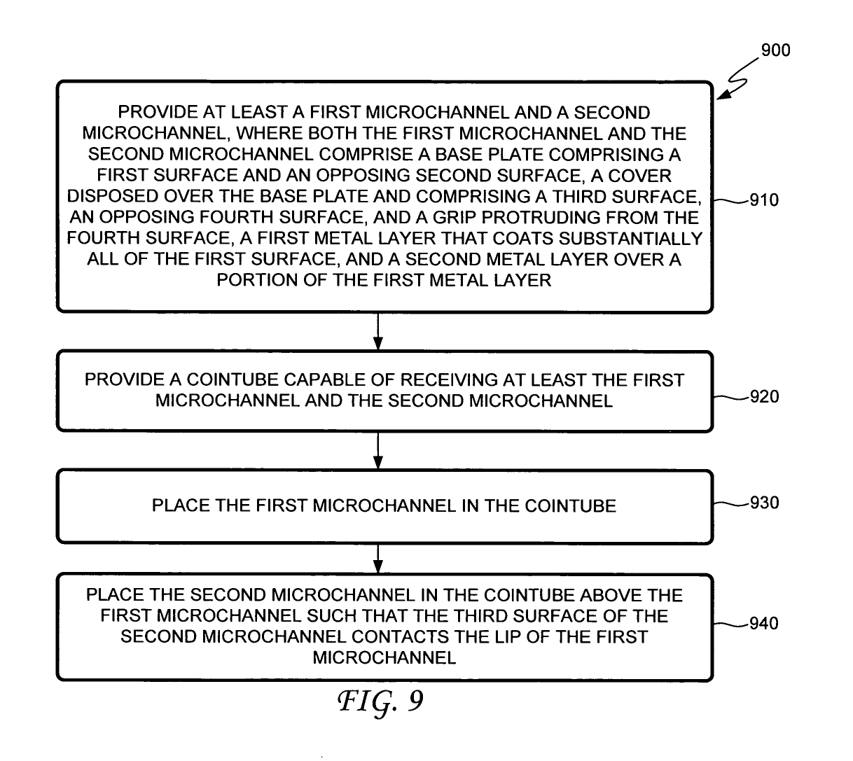

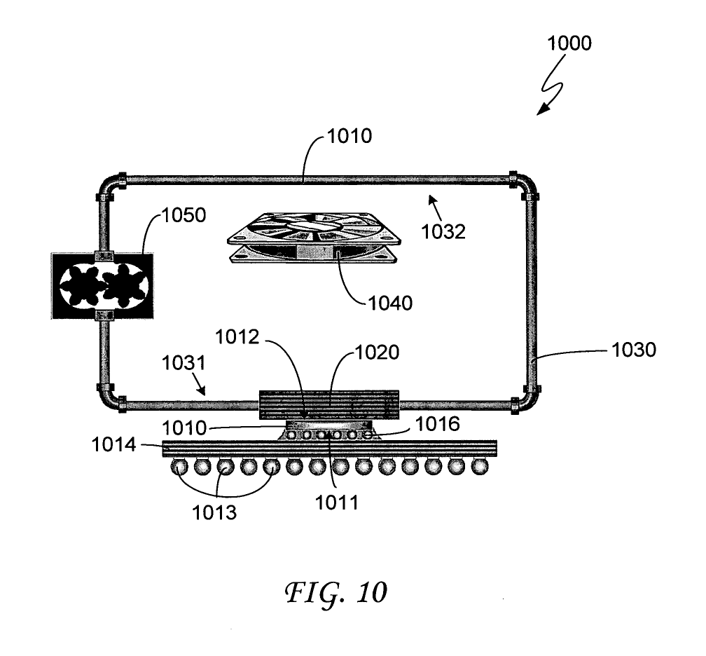

FIG. 9 is a flowchart illustrating a method 900 of preparing a microchannel for transport according to an embodiment of the invention. A step 910 of method 900 is to provide at least a first microchannel and a second microchannel, where both the first microchannel and the second microchannel comprise: a base plate comprising a first surface, a second surface spaced apart from the first surface, and a plurality of fins at the second surface; a cover disposed over the base plate and comprising a third surface having a cavity therein capable of receiving the plurality of fins, a fourth surface spaced apart from the third surface, and a grip protruding from the fourth surface; a first metal layer that coats substantially all of the first surface; and a second metal layer over a portion of the first metal layer. As an example, the microchannels provided in step 910 can be similar to one of microchannels 200, 400, and 500, first shown in FIGS. 2, 4, and 5, respectively.

A step 920 of method 900 is to provide a cointube capable of receiving at least the first microchannel and the second microchannel. As an example, the cointube can be similar to cointube 800 shown in FIG. 8.

A step 930 of method 900 is to place the first microchannel in the cointube and a step 940 of method 900 is to place the second microchannel in the cointube above the first microchannel such that the third surface of the second microchannel contacts the lip of the first microchannel. In this way the first surface of the second microchannel, which is where the second metal layer of the second microchannel is located, will not contact the first microchannel. Thus, the second metal layer is protected so that it is not scratched or damaged during transport. Such protection is important because scratches or the like on the second metal layer are likely to lead to problems with solderability.

FIG. 10 is a schematic view of a system 1000 in which a heat spreader according to an embodiment of the invention may be utilized. As illustrated in FIG. 10, system 1000 comprises a processing device 1010 such as an integrated circuit die disposed on a substrate 1014 to which it is attached via solder bumps 1016 or other first line interconnect. Solder balls 1013 form part of a ball grid array or other second line interconnect connecting substrate 1014 to a system board (not shown) such as a printed circuit board or the like. Processing device 1010 has a front side 1011 and a back side 1012. A microchannel 1020 or other heat spreader is positioned adjacent to back side 1012 of processing device 1010 and attached thereto via thermal interface materials such as solder or polymer materials. It will be understood that the foregoing is merely an exemplary mounting scheme and is not meant to be limiting. In an alternative embodiment, for example, processing device 1010 may be electrically coupled to various other systems, components, or devices. The details of microchannel 1020 are not shown in FIG. 10. However, microchannel 1020 is similar to one of heat spreader 100 or microchannels 200, 400, or 500, first shown in FIGS. 1, 2, 4, and 5, respectively.

System 1000 further comprises a cooling loop 1030 that has a portion 1031 adjacent to microchannel 1020 and a portion 1032 spaced apart from portion 1031, and a cooling device 1040, such as a cooling fan or the like, positioned adjacent to portion 1032 in which a coolant (not shown) circulates. In one embodiment system 1000 still further comprises a pump 1050 coupled to the cooling loop.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the heat spreader and related structures and methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A heat spreader for use in conjunction with a semiconducting device, the heat spreader comprising:
a body having a first surface and a second surface, the first surface and the second surface being spaced apart from each other;
a first metal layer coating substantially all of the body;
a second metal layer over a portion of the first metal layer at the first surface; and
a lip protruding from the second surface.

2. The heat spreader of claim 1 wherein:
the body comprises copper.

3. The heat spreader of claim 2 wherein:
the first metal layer comprises nickel; and
the second metal layer comprises gold.

4. A microchannel for use in conjunction with a semiconducting device, the microchannel comprising:
a base plate comprising:
a first surface;
a second surface spaced apart from the first surface; and
a plurality of fins at the second surface; and
a cover disposed over the base plate, the cover comprising:
a third surface having a cavity therein capable of receiving the plurality of fins;
a fourth surface spaced apart from the third surface; and
a grip adjacent to the fourth surface.

5. The microchannel of claim 4 wherein:
the cover, the plurality of fins, and the base plate are made of copper.

6. The microchannel of claim 5 wherein:
the cover further comprises a fluid aperture.

7. The microchannel of claim 4 wherein:
the grip comprises a lip protruding from the fourth surface.

8. The microchannel of claim 7 wherein:
the lip is one of a plurality of lips protruding from the fourth surface.

9. The microchannel of claim 8 wherein:
the lip is one of four lips protruding from the fourth surface.

10. The microchannel of claim 7 wherein:
the lip forms a substantially continuous ring on the fourth surface.

11. The microchannel of claim 4 wherein:
the grip comprises a depression in the fourth surface.

12. The microchannel of claim 11 wherein:
the depression is one of a plurality of depressions in the fourth surface.

13. The microchannel of claim 4 wherein:
adjacent ones of the plurality of fins are spaced apart from each other by a distance of approximately 50 micrometers.

14. The microchannel of claim 4 wherein:
the base plate has a thickness no greater than approximately 500 micrometers.

15. The microchannel of claim 4 further comprising:
a first metal layer that coats substantially all of the first surface and the fourth surface and a portion of the third surface; and
a second metal layer over a portion of the first metal layer at the first surface.

16. A method of manufacturing a heat spreader for use in conjunction with a semiconducting device, the method comprising:
providing a body having a first surface and a second surface spaced apart from each other;
forming a grip adjacent to the second surface; and
flattening the first surface.

17. The method of claim 16 wherein:
forming the grip comprises forming a lip protruding from the second surface.

18. The method of claim 16 wherein:
forming the grip comprises forming a depression in the second surface.

19. The method of claim 16 wherein:
flattening the first surface comprises at least one of:
polishing the first surface; and
grinding the first surface.

20. A method of manufacturing a microchannel for use in conjunction with a semiconducting device, the method comprising:
providing a base plate comprising:
a first surface;
a second surface spaced apart from the first surface; and
a plurality of fins at the second surface;
providing a cover comprising:
a third surface having a cavity therein capable of receiving the plurality of fins;
a fourth surface spaced apart from the third surface; and
a grip adjacent to the fourth surface;
disposing the cover over the base plate; and
flattening the first surface.

21. The method of claim 20 further comprising:
coating at least a portion of the base plate with a first metal layer; and
placing a second metal layer over a portion of the first metal layer.

22. The method of claim 20 wherein:
forming the grip comprises forming a lip protruding from the fourth surface.

23. The method of claim 20 wherein:
forming the grip comprises forming a depression in the fourth surface.

24. The method of claim 20 wherein:
flattening the first surface comprises at least one of:
polishing the first surface; and
grinding the first surface.

25. The method of claim 24 wherein:
flattening the first surface further comprises flattening the first surface to a flatness of approximately 35 micrometers.

26. The method of claim 20 wherein:
disposing the cover over the base plate comprises:
positioning the cover over the base plate such that the plurality of fins are in the cavity;
placing a brazing material on at least a portion of at least one of the base plate and the cover; and
brazing the base plate and the cover to each other.

27. A method of preparing a microchannel for transport, the method comprising:
providing at least a first microchannel and a second microchannel, where both the first microchannel and the second microchannel comprise:
a base plate comprising:
a first surface;
a second surface spaced apart from the first surface; and
a plurality of fins at the second surface; and
a cover disposed over the base plate, the cover comprising:
a third surface having a cavity therein capable of receiving the plurality of fins;
a fourth surface spaced apart from the third surface; and
a grip protruding from the fourth surface;
a first metal layer that coats substantially all of the first surface; and
a second metal layer over a portion of the first metal layer;
providing a cointube capable of receiving at least the first microchannel and the second microchannel;
placing the first microchannel in the cointube; and
placing the second microchannel in the cointube above the first microchannel such that the third surface of the second microchannel contacts the grip of the first microchannel.

28. The method of claim 27 wherein:
providing at least the first microchannel and the second microchannel comprises providing the grip to be one of a plurality of grips protruding from the fourth surface.

29. The method of claim 28 wherein:
providing at least the first microchannel and the second microchannel comprises providing the grip to be one of four grips protruding from the fourth surface.

30. The method of claim 27 wherein:
providing at least the first microchannel and the second microchannel comprises providing the grip to be a substantially continuous ring on the fourth surface.

31. A system comprising:
a board;
a processing device disposed on the board, the processing device having a front side and a back side;
a microchannel adjacent to the back side of the processing device;
a cooling loop having a first portion adjacent to the microchannel and a second portion spaced apart from the first portion;
a cooling device adjacent to the second portion of the cooling loop; and
a coolant in the cooling loop,
wherein:
the microchannel comprises:
a base plate comprising a plurality of fins; and
a cover disposed over the base plate, the cover comprising:
a first surface having a cavity therein capable of receiving the plurality of fins;
a second surface spaced apart from the first surface; and
a grip adjacent to the second surface.

32. The system of claim 31 wherein:
the cover, the plurality of fins, and the base plate are made of copper.

33. The system of claim 32 further comprising:
a first metal layer that coats a portion of the base plate;
a second metal layer over a portion of the first metal layer; and
a pump coupled to the cooling loop.

34. The system of claim 33 wherein:
the grip comprises a lip protruding from the second surface.

35. The system of claim 34 wherein:
the lip forms a substantially continuous ring on the second surface.

36. The system of claim 33 wherein:
the grip comprises a depression in the second surface.
